(19) United States
(12) Patent Application Publication
(10) Pub. No.: US 2026/0104723 A1
(43) Pub. Date: Apr. 16, 2026

(54) Voltage Control in Memory Devices

(71) Applicant: Yangtze Memory Technologies Co., Ltd., Wuhan (CN)

(72) Inventor: Ning ZHANG, Wuhan (CN)

(21) Appl. No.: 18/940,257

(22) Filed: Nov. 7, 2024

(30) Foreign Application Priority Data
Oct. 11, 2024 (CN) 202411419250.9

(51) Int. Cl. G05F 1/569; G11C 16/04; G11C 16/08; G11C 16/16; G11C 16/26; H10B 41/27; H10B 41/35; H10B 41/41; H10B 43/27; H10B 43/35; H10B 43/40

(52) U.S. Cl. CPC G05F 1/569; G11C 16/0483; G11C 16/08; G11C 16/16; G11C 16/26; H10B 41/27; H10B 41/35; H10B 41/41; H10B 43/27; H10B 43/35; H10B 43/40

(57) ABSTRACT

Example low dropout (LDO) regulators, memory devices, and systems for voltage control in memory devices are disclosed. One example LDO regulator includes a transistor, an amplifier, and a clamping circuit. An output of the LDO regulator is coupled to a first terminal of the transistor. An output of the clamping circuit is coupled to a gate terminal of the transistor. An output of the amplifier is coupled to the gate terminal of the transistor.

### CROSS-REFERENCE TO RELATED APPLICATIONS

This application claims priority to Chinese Patent Application No. 202411419250.9, filed on Oct. 11, 2024, which is hereby incorporated by reference in its entirety.

### TECHNICAL FIELD

The present disclosure relates to memory devices, systems, and methods for voltage control in memory devices.

### BACKGROUND

Voltage generators can provide voltages to support operations in memory devices. An example of a memory device is a flash memory. Flash memory is a low-cost, high-density, nonvolatile solid-state storage medium that can be electrically erased and reprogrammed. Flash memory includes NOR flash memory and NAND flash memory. Various operations can be performed by flash memories, for example, read, program (write), and erase operations.

### SUMMARY

The present disclosure relates to low dropout (LDO) regulators, memory devices, and systems for voltage control in memory devices.

Certain aspects of the subject matter described here can be implemented as an LDO regulator. The LDO regulator includes a transistor, an amplifier, and a clamping circuit. An output of the LDO regulator is coupled to a first terminal of the transistor. An output of the clamping circuit is coupled to a gate terminal of the transistor. An output of the amplifier is coupled to the gate terminal of the transistor.

The LDO regulator can include one or more of the following features.

In some implementations, the clamping circuit includes a first field-effect transistor (FET) and a second FET, a gate terminal of the first FET is coupled to the gate terminal of the transistor, the gate terminal of the first FET is coupled to a first terminal of the second FET, and a first terminal of the first FET is coupled to a gate terminal of the second FET.

In some implementations, the clamping circuit includes a first resistance coupled to the first terminal of the second FET, and a voltage of the gate terminal of the first FET is a difference between a threshold voltage of the first FET and a product of a resistance value of the first resistance and a current through the first FET.

In some implementations, the clamping circuit includes a current mirror and a third FET, a first terminal of the third FET is coupled to a first terminal of an input FET of the current mirror, and the first terminal of the first FET is coupled to a first terminal of an output FET of the current mirror.

In some implementations, the third FET includes a plurality of transistors that are connected in parallel and are configured to adjust a current through the input FET of the current mirror.

In some implementations, a ratio between a current through the first FET and a current through the input FET of the current mirror is fixed when the clamping circuit is operating.

In some implementations, the clamping circuit includes a fourth FET, a first terminal of the fourth FET is coupled to a second terminal of the output FET of the current mirror, and a second terminal of the fourth FET is coupled to a second terminal of the second FET.

In some implementations, the transistor and the first FET are transistors of the same type.

In some implementations, the LDO regulator is coupled to a second LDO regulator, and the first terminal of the transistor in the LDO regulator is coupled to a first terminal of a transistor in the second LDO regulator.

In some implementations, an output of a second clamping circuit is coupled to a gate terminal of the transistor in the second LDO regulator.

In some implementations, the transistor is an n-channel metal-oxide-semiconductor (NMOS) transistor.

Certain aspects of the subject matter described here can be implemented as a memory device. The memory device includes a memory cell array and a peripheral circuit coupled to the memory cell array and including an LDO regulator. The LDO regulator includes a transistor, an amplifier, and a clamping circuit. An output of the LDO regulator is coupled to a first terminal of the transistor. An output of the clamping circuit is coupled to a gate terminal of the transistor. An output of the amplifier is coupled to the gate terminal of the transistor.

The memory device can include one or more of the following features.

In some implementations, the clamping circuit includes a first field-effect transistor (FET) and a second FET, a gate terminal of the first FET is coupled to the gate terminal of the transistor, the gate terminal of the first FET is coupled to a first terminal of the second FET, and a first terminal of the first FET is coupled to a gate terminal of the second FET.

In some implementations, the clamping circuit includes a first resistance coupled to the first terminal of the second FET, and a voltage of the gate terminal of the first FET is a difference between a threshold voltage of the first FET and a product of a resistance value of the first resistance and a current through the first FET.

In some implementations, the clamping circuit includes a current mirror and a third FET, a first terminal of the third FET is coupled to a first terminal of an input FET of the current mirror, and the first terminal of the first FET is coupled to a first terminal of an output FET of the current mirror.

In some implementations, the third FET includes a plurality of transistors that are connected in parallel and are configured to adjust a current through the input FET of the current mirror.

In some implementations, a ratio between a current through the first FET and a current through the input FET of the current mirror is fixed when the clamping circuit is operating.

In some implementations, the clamping circuit includes a fourth FET, a first terminal of the fourth FET is coupled to a second terminal of the output FET of the current mirror, and a second terminal of the fourth FET is coupled to a second terminal of the second FET.

In some implementations, the transistor and the first FET are transistors of the same type.

Certain aspects of the subject matter described here can be implemented as a memory system. The memory system includes a memory device and a controller coupled to the memory device and configured to initiate operations. The memory device includes a memory cell array and a peripheral circuit coupled to the memory cell array and including an LDO regulator. The LDO regulator includes a transistor, an amplifier, and a clamping circuit. An output of the LDO regulator is coupled to a first terminal of the transistor. An output of the clamping circuit is coupled to a gate terminal of the transistor. An output of the amplifier is coupled to the gate terminal of the transistor.

The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic circuit diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates an example memory device that includes some example peripheral circuits and a memory cell array, according to some aspects of the present disclosure.

FIG. 4 illustrates an example low dropout (LDO) regulator, according to some aspects of the present disclosure.

FIG. 5 illustrates an example transient response of the LDO regulator in FIG. 4, according to some aspects of the present disclosure.

FIG. 6 illustrates an example LDO regulator that includes a clamping circuit and the LDO regulator in FIG. 4, according to some aspects of the present disclosure.

FIG. 7 illustrates an example of the clamping circuit in FIG. 6 that is coupled to the LDO regulator in FIG. 4, according to some aspects of the present disclosure.

FIG. 8A illustrates an example of two LDO regulators that are coupled to each other, according to some aspects of the present disclosure.

FIG. 8B illustrates an example of the difference between two gate voltages V_{g1} and V_{g2} of transistors Mₚ₁ and Mₚ₂ in FIG. 8A, according to some aspects of the present disclosure.

FIG. 9 illustrates another example of two LDO regulators that are coupled to each other, according to some aspects of the present disclosure.

FIG. 10 illustrates a block diagram of an example system having a memory device, according to some aspects of the present disclosure.

FIG. 11A illustrates a diagram of a memory card having a memory device, according to some aspects of the present disclosure.

FIG. 11B illustrates a diagram of a solid-state drive (SSD) having a memory device, according to some aspects of the present disclosure.

Like reference numbers and designations in the various drawings indicate like elements.

### DETAILED DESCRIPTION

A low dropout (LDO) regulator can be used to maintain a steady output voltage of a voltage generator that provides power to different components in a memory device (e.g., a NAND memory device). In some cases, an LDO regulator can include a transistor (e.g., a field effect transistor (FET)) and an amplifier (e.g., an error amplifier). When the memory device performs certain operations, for example, a read operation, a transient load current of the voltage generator can occur and therefore lead to an overshoot of the output voltage of the LDO regulator. Consequently, the gate voltage of the transistor in the LDO regulator can decrease to a level such that the transient response time of the LDO regulator increases.

This specification relates to LDO regulators, memory devices, and systems that use a clamping circuit coupled to the gate of the transistor in the LDO regulator to prevent the gate voltage of the transistor from going below a predetermined threshold, when a transient load current occurs at the output of the LDO regulator, and therefore avoid having increased transient response time of the LDO regulator. In some cases, the clamping circuit can include two transistors used to clamp the gate voltage of the LDO regulator, as well as a current mirror and a third transistor used to control the level of the clamped gate voltage of the LDO regulator.

Implementations of the present disclosure can provide one or more of the following technical effects. For example, an LDO regulator coupled to a voltage generator can use the clamping circuit to avoid having an increased transient response time of the LDO regulator, when a transient load current occurs at the output of the LDO regulator, and therefore ensure that voltages above predetermined thresholds can be provided by the voltage generator to different components in a memory device during operations such as read or program operations of the memory device. Furthermore, the proposed clamping circuit can be implemented without increasing the die size of the memory device, while keeping the power consumption of the memory device at a relatively low level.

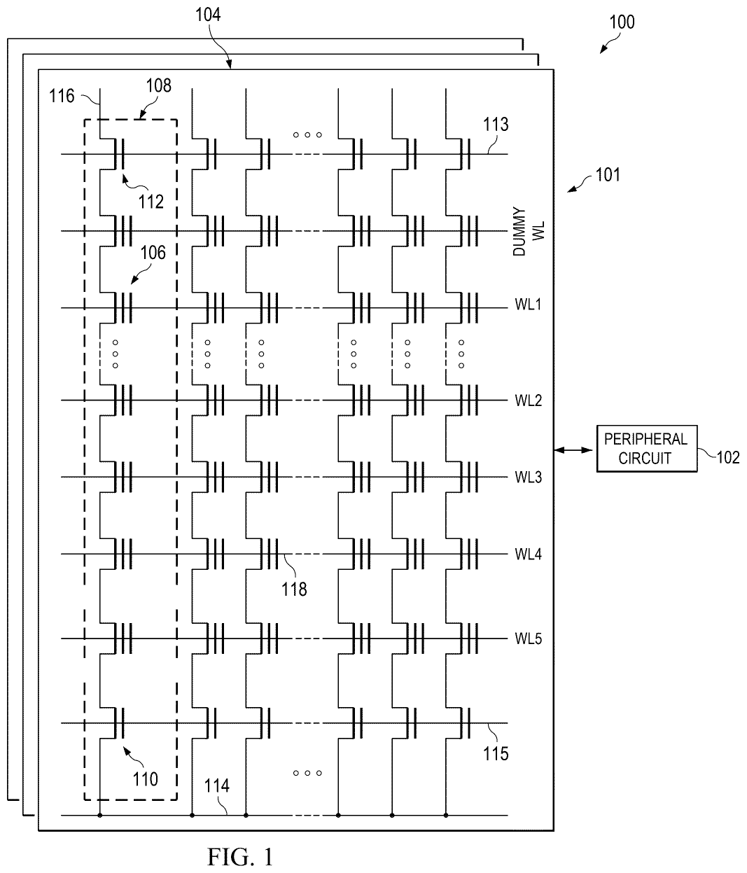

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 and DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage (e.g., 0 V) to respective DSG 112 through one or more DSG lines 113, and/or by applying a select voltage or a deselect voltage (e.g., 0 V) to respective SSG 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Vers), such as a high positive voltage (e.g., 20 V or more). In some examples, erase operation may be performed at a half-block level, a quarter-block level, or a level having any suitable number of blocks or any suitable fractions of a block. Memory cells 106 of adjacent NAND memory strings can be coupled through word lines 118 that select which row of memory cells 106 is affected by read and program operations. Each word line 118 can include a plurality of control gates (gate electrodes) at each memory cell 106 and a gate line coupling the control gates. Example word lines (WLs) shown in FIG. 1 include dummy WL, WL1, WL2, WL3, WL4, and WL5 that are between one or more DSG lines 113 and one or more SSG lines 115.

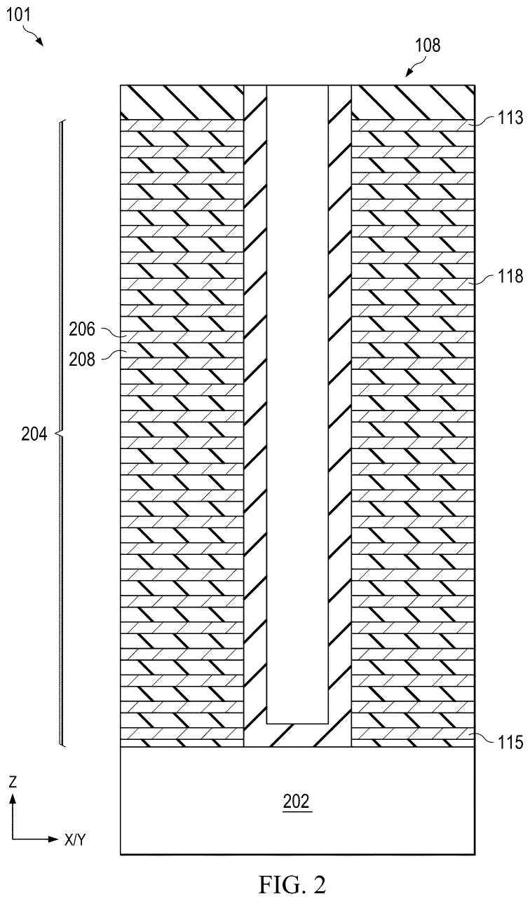

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, DSG 112, or SSG 110, and can extend laterally as DSG line 113 at the top of memory stack 204, SSG line 115 at the bottom of memory stack 204, or word line 118 between DSG line 113 and SSG line 115.

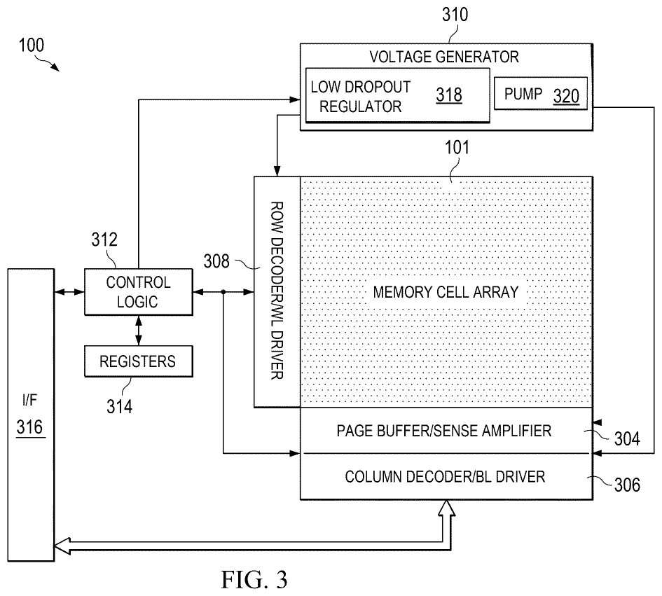

Peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each target memory cell of the memory cells 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense, for example, at sensing node (SO) 418, the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Row decoder/word line driver 308 can be configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Voltage generator 310 can include low dropout regulator 318 and pump 320. The output voltage of pump 320 can be regulated by low dropout regulator 318, and the regulated voltage of pump 320 can be used as output of voltage generator 310, for example, when voltage generator 310 provides relatively low voltages (e.g., less than 1V) to some components of memory device 100, such as page buffer/sense amplifier 304, a high speed data interface (e.g., a data path), or word lines 118 in memory device 100.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. The status registers of registers 314 can include one or more registers configured to store open block information indicative of the open block(s) of all blocks 104 in memory cell array 101, such as having an auto dynamic start voltage (ADSV) list. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

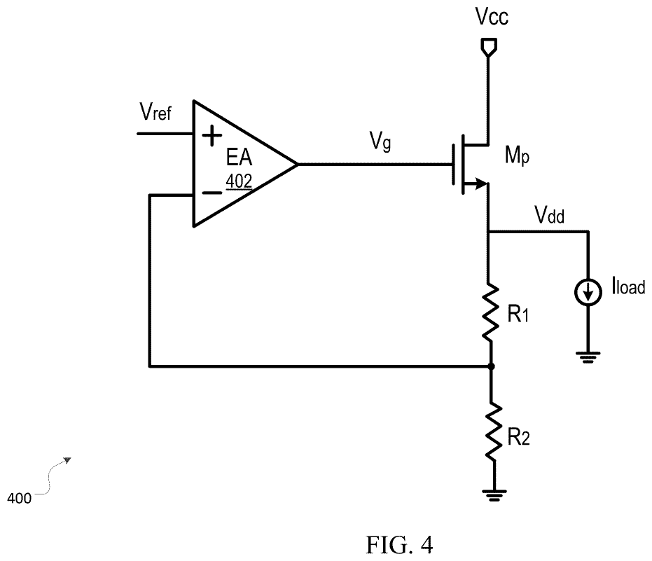

FIG. 4 illustrates an example LDO regulator 400, according to some aspects of the present disclosure. In some implementations, LDO regulator 400 can be an example of LDO regulator 318 in FIG. 3. LDO regulator 400 can include a transistor Mₚ, for example, an FET, and amplifier 402, for example, an error amplifier (EA), that is coupled to the transistor Mₚ. As shown in FIG. 4, the output of LDO regulator 400 is coupled to a terminal (i.e., first terminal) of the transistor Mₚ, and the output of amplifier 402 is coupled to the gate terminal of the transistor Mₚ. LDO regulator 400 also includes two resistors R₁ and R₂ that can be used together with V_{ref} to control the output voltage V_{dd} of LDO regulator 400, as shown in Equation 1 below, where V_{ref} is the reference input voltage of amplifier 402. In some cases, the output voltage V_{dd} of LDO regulator 400 can be provided to some components in a memory device, for example, page buffer/sense amplifier 304 or a high speed data interface (e.g., a data path). V_{ref} can be provided by a stable power supply and may not be affected by temperature changes or changes in voltage V_{cc} that is applied at a second terminal of the transistor Mₚ. An example value of V_{cc} is 3V.

$${V}_{dd} = {V}_{ref} * ( 1 + \frac{{R}_{1}}{{R}_{2}} ) \qquad ( 1 )$$

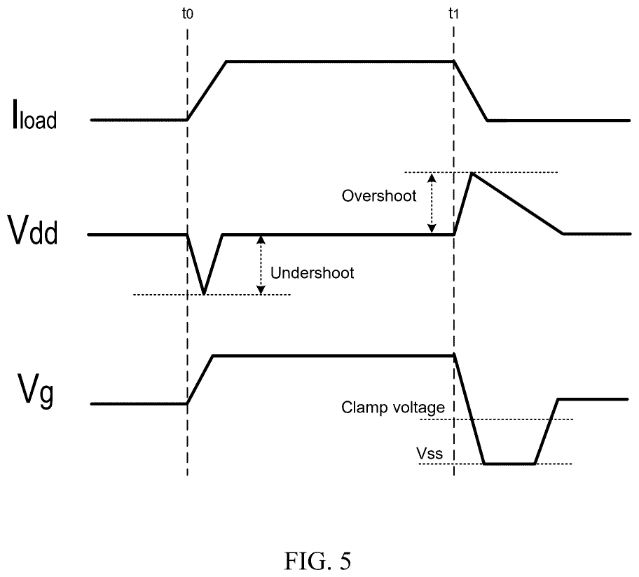

FIG. 5 illustrates an example transient response of LDO regulator 400, according to some aspects of the present disclosure. In some implementations, the onset of the load current I_{load} (at time t₀) can lead to an undershoot of the output voltage V_{dd} of LDO regulator 400, which in turn can lead to an increase of the gate voltage V_{g} of the transistor Mₚ in LDO regulator 400. Consequently the transistor Mₚ is turned on.

In some implementations, the end of the load current I_{load} (at time t₁) can lead to an overshoot of the output voltage V_{dd}, which in turn can lead to a decrease of the gate voltage V_{g} of the transistor Mₚ to a voltage Vₛₛ (e.g., 0V). Consequently the transistor Mₚ is turned off, and the transient response time of LDO regulator 400 increases due to the gate voltage V_{g} of the transistor Mₚ being reduced to Vₛₛ.

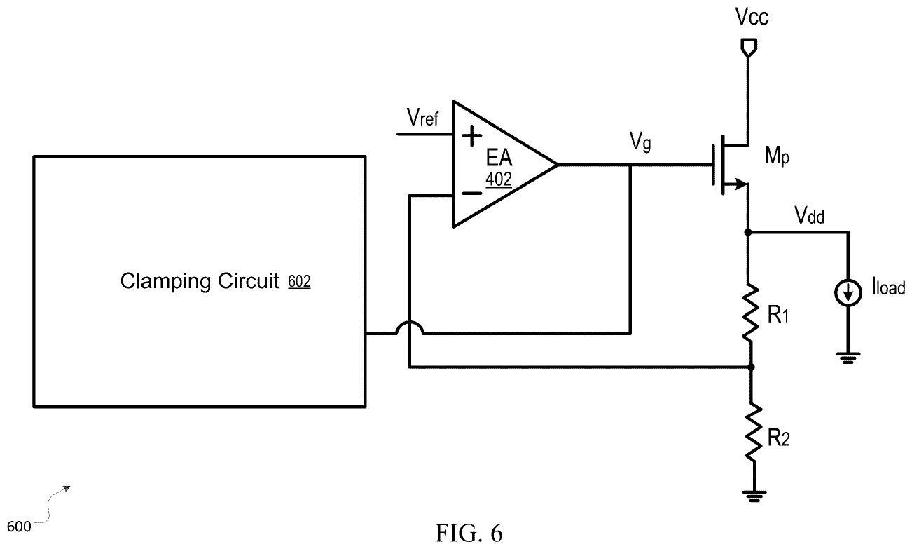

In some implementations, to prevent the decrease of the gate voltage V_{g} of the transistor Mₚ to the voltage Vₛₛ, a clamping circuit, for example, clamping circuit 602 in FIG. 6, can be coupled to LDO regulator 400 to clamp the output voltage V_{dd} of LDO regulator 400 at the clamp voltage in FIG. 5 that is higher than Vₛₛ, when the overshoot in V_{dd} occurs at time t₁. An example value of the clamp voltage in FIG. 5 is 0.7V. The clamping circuit is described in more detail next.

FIG. 6 illustrates an example LDO regulator 600 that includes clamping circuit 602 and LDO regulator 400, according to some aspects of the present disclosure. In some implementations, the output of clamping circuit 602 is coupled to the gate terminal of the transistor Mₚ to clamp the gate voltage V_{g} of the transistor Mₚ at a voltage, for example, the clamp voltage in FIG. 5, that is higher than Vₛₛ, when the overshoot in V_{dd} occurs. Because the clamp voltage is higher than Vₛₛ, clamping circuit 602 can be used in LDO regulator 600 to avoid the increased transient response time of LDO regulator 400 described above.

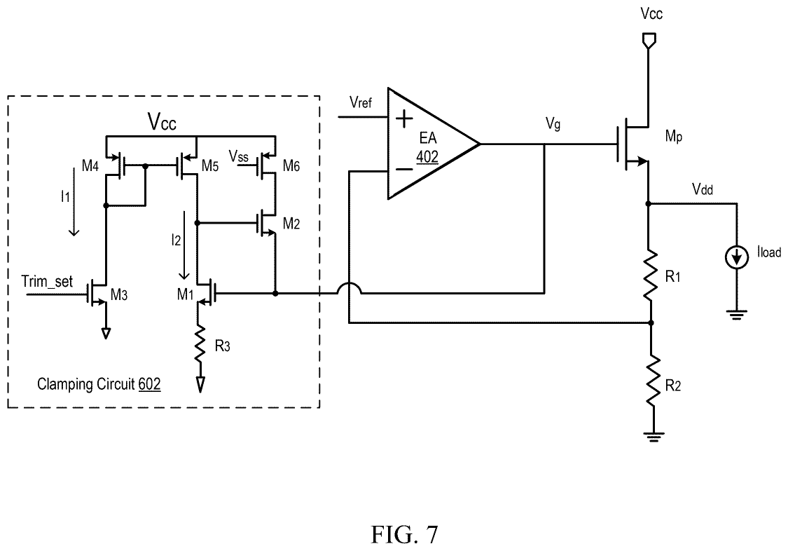

FIG. 7 illustrates an example of clamping circuit 602 that is coupled to LDO regulator 400, according to some aspects of the present disclosure. In some implementations, clamping circuit 602 includes a FET M₁ (i.e., first FET) and a FET M₂ (i.e., second FET). The gate terminal of the FET M₁ is coupled to the gate terminal of the transistor Mₚ in LDO regulator 400. The gate terminal of the FET M₁ is also coupled to a terminal of the FET M₂ (i.e., first terminal of the second FET). A terminal of the FET M₁ (i.e., first terminal of the first FET) is coupled to the gate terminal of the FET M₂. In some cases, the transistor Mₚ and the FET M₁ are transistors of the same type. In some cases, when the gate voltage V_{g} of the transistor Mₚ is at a relatively high level (e.g., at a V_{g} level between to and t₁ in FIG. 5), the FET M₁ is turned on and consequently the gate voltage of the FET M₂ decreases such that the FET M₂ is turned off. When the gate voltage V_{g} of the transistor Mₚ decreases to a relatively low level (e.g., at a V_{g} level after t₁ in FIG. 5), the FET M₁ is turned off, and consequently the gate voltage of the FET M₂ increases such that the FET M₂ is turned on. Therefore the gate voltage V_{g} of the transistor Mₚ can be clamped at a relatively high level determined by Equation 2, as described below.

In some implementations, the voltage of the gate terminal of the transistor Mₚ (e.g., V_{clamp_ngate} in Equation 2) can be clamped by clamping circuit 602 using Equation 2 below.

$${V}_{clamp\_ngate} = {I}_{2} * {R}_{3} - \vert {V}_{TH} \vert \qquad ( 2 )$$

where I₂ is the current through the FET M₁, R₃ is the resistance value of the resistor coupled to a second terminal of the FET M₁. In some cases, |V_{TH}| can be 0V. Therefore, the gate voltage V_{g} of the transistor Mₚ can be controlled by I₂ that goes through the FET M₁.

In some implementations, clamping circuit 602 includes a current mirror and a FET M₃ (i.e., third FET) that together can be used to adjust the value of 12. The current mirror can include an input FET M₄ and an output FET M₅. A terminal of FET M₃ (i.e., first terminal of the third FET) is coupled to a terminal of the input FET M₄ (i.e., first terminal of an input FET) of the current mirror, and the terminal of the FET M₁ (i.e., first terminal of the first FET) is coupled to a terminal of the output FET M₅ (i.e., first terminal of an output FET) of the current mirror. In some cases, each of the input FET M₄ and the output FET M₅ can include multiple transistors connected in parallel. A ratio between a current I₂ going through the FET M₁ and a current I₁ going through the input FET M₄ of the current mirror can be adjusted by controlling the total number of transistors in the input FET M₄ that are turned on and the total number of transistors in the output FET M₅ that are turned on. The ratio between I₂ and I₁ can be fixed when clamping circuit 602 is operating. In some cases, the FET M₃ can have multiple transistors that are connected in parallel and are configured to adjust the current I₁ going through the input FET M₄ of the current mirror. By adjusting the total number of transistors in the FET M₃ that are turned on, the current I₁ can be adjusted. Therefore, by adjusting the current I₁, the current I₂ can be adjusted accordingly through the ratio between I₂ and I₁, and the voltage of the gate terminal of the transistor Mₚ can be controlled by I₂ accordingly.

In some implementations, clamping circuit 602 includes a FET M₆ (i.e. fourth FET). A terminal of the FET M₆ (i.e., first terminal of the fourth FET) is coupled to a second terminal of the output FET of the current mirror, and a second terminal of the FET M₆ is coupled to a second terminal of the FET M₄. A voltage Vₛₛ can be applied to the gate terminal of the FET M₆. In some cases, the FET M₆ can be used for electrostatic discharge (ESD) protection of clamping circuit 602.

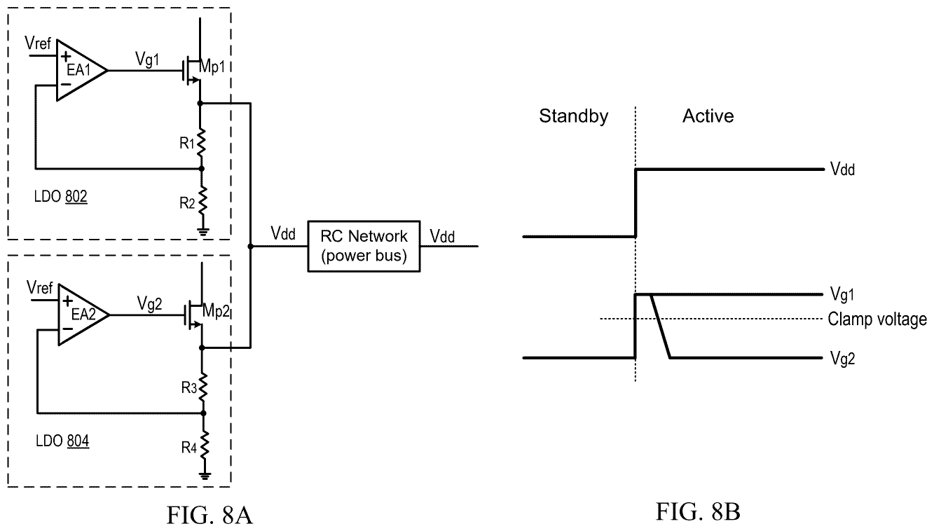

FIG. 8A illustrates an example of two LDO regulators 802 and 804 that are coupled to each other, according to some aspects of the present disclosure. Each of the two LDO regulators 802 and 804 can be an example of LDO regulator 400. In some implementations, a terminal of the transistor Mₚ₁ in LDO regulator 802 is coupled to a terminal of the transistor Mₚ₂ in LDO regulator 804. In some cases, the two LDO regulators 802 and 804 can be used together to reduce the transient response time when compared to scenarios with only one LDO regulator.

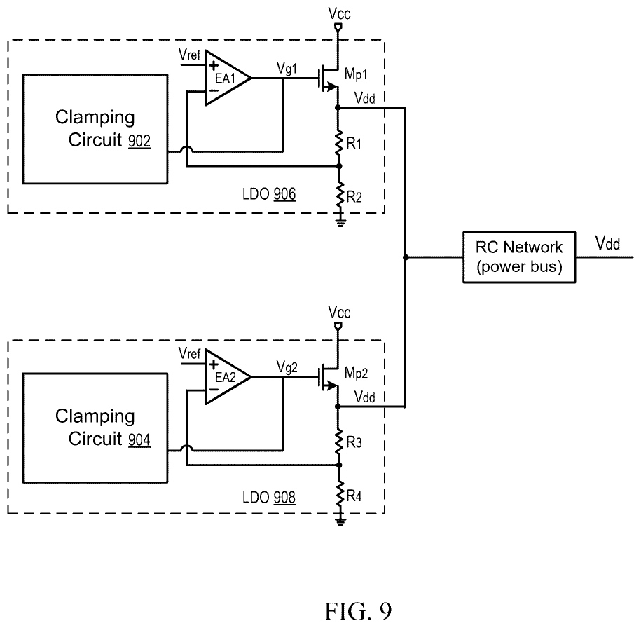

FIG. 8B illustrates an example of the difference between two gate voltages V_{g1} and V_{g2} of transistors Mₚ₁ and Mₚ₂ in FIG. 8A, according to some aspects of the present disclosure. In some implementations, the difference between V_{g1} and V_{g2} can be due to differences in parameters between LDO regulators 802 and 804, for example, between parameters of transistors Mₚ₁ and Mₚ₂, and consequently one of the two gate voltages V_{g1} and V_{g2} decreases to a relatively low level. For example, V_{g2} is lower than V_{g1} in FIG. 8B. To reduce the difference between V_{g1} and V_{g2}, each of the two LDO regulators 802 and 804 in FIG. 8A can be coupled to a corresponding clamping circuit, as shown in FIG. 9.

FIG. 9 illustrates an example of two LDO regulators 906 and 908 that are coupled to each other, with each LDO regulator having a clamping circuit, according to some aspects of the present disclosure. Each of the two LDO regulators 906 and 908 in FIG. 9 can be an example of LDO regulator 600. In some implementations, when one of the gate voltages V_{g1} and V_{g2} (e.g., V_{g2} in FIG. 8B) is lower than the other gate voltage (e.g., V_{g1} in FIG. 8B), the clamping circuit (e.g., 904) that is coupled to the transistor (e.g., Mₚ₂ in FIG. 9) with lower gate voltage (e.g., V_{g2} in FIG. 8B) can clamp the gate voltage of that transistor to a clamp voltage (e.g., the clamp voltage in FIG. 8B) that is higher than the lower voltage (e.g., V_{g2} in FIG. 8B), therefore reducing the transient response time of the LDO regulator (e.g., 908) having the lower gate voltage than that of the other LDO regulator.

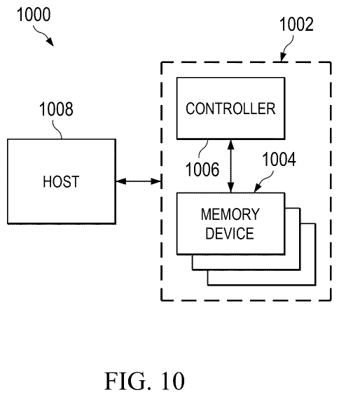

FIG. 10 illustrates a block diagram of an example system 1000 having a memory device, according to some aspects of the present disclosure. System 1000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, system 1000 can include a host 1008 and a memory system 1002 having one or more memory devices 1004 and a memory controller 1006. Host 1008 can be a processor of an electronic device, such as a central processing unit (CPU), or a system-on-chip (SoC), such as an application processor (AP). Host 1008 can be configured to send or receive data to or from memory devices 1004.

Memory device 1004 can be any memory device disclosed in the present disclosure. Memory controller 1006 is coupled to memory device 1004 and host 1008 and is configured to control memory device 1004, according to some implementations. Memory controller 1006 can manage the data stored in memory device 1004 and communicate with host 1008. In some implementations, memory controller 1006 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1006 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1006 can be configured to control operations of memory device 1004, such as read, erase, and program operations. Memory controller 1006 can also be configured to manage various functions with respect to the data stored or to be stored in memory device 1004 including, but not limited to bad-block management, garbage collection, logical-to-physical address conversion, wear leveling, etc. In some implementations, memory controller 1006 is further configured to process error correction codes (ECCs) with respect to the data read from or written to memory device 1004. Any other suitable functions may be performed by memory controller 1006 as well, for example, formatting memory device 1004.

Memory controller 1006 can communicate with an external device (e.g., host 1008) according to a particular communication protocol. For example, memory controller 1006 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

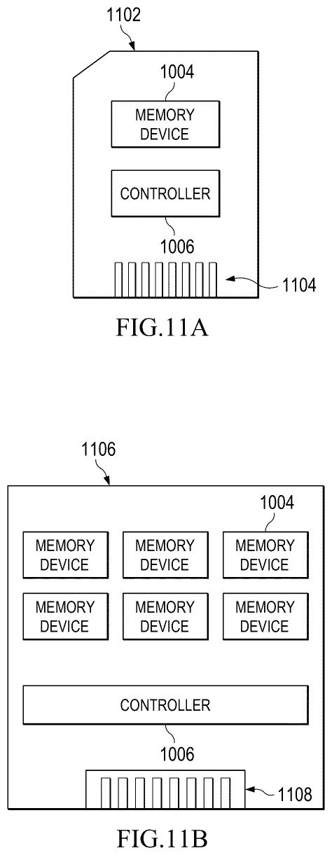

Memory controller 1006 and one or more memory devices 1004 can be integrated into various types of storage devices, for example, be included in the same package, such as a universal Flash storage (UFS) package or an eMMC package. That is, memory system 1002 can be implemented and packaged into different types of end electronic products. In one example shown in FIG. 11A, memory controller 1006 and a single memory device 1004 may be integrated into a memory card 1102. Memory card 1102 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1102 can further include a memory card connector 1104 coupling memory card 1102 with a host (e.g., host 1008 in FIG. 10). In another example shown in FIG. 11B, memory controller 1006 and multiple memory devices 1004 may be integrated into an SSD 1106. SSD 1106 can further include an SSD connector 1108 coupling SSD 1106 with a host (e.g., host 1008 in FIG. 10). In some implementations, the storage capacity and/or the operation speed of SSD 1106 is greater than those of memory card 1102.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A low dropout (LDO) regulator, comprising:
a transistor;
an amplifier; and
a clamping circuit, wherein:
an output of the LDO regulator is coupled to a first terminal of the transistor;
an output of the clamping circuit is coupled to a gate terminal of the transistor; and
an output of the amplifier is coupled to the gate terminal of the transistor.

2. The LDO regulator according to claim 1, wherein the clamping circuit comprises a first field-effect transistor (FET) and a second FET, a gate terminal of the first FET is coupled to the gate terminal of the transistor, the gate terminal of the first FET is coupled to a first terminal of the second FET, and a first terminal of the first FET is coupled to a gate terminal of the second FET.

3. The LDO regulator according to claim 2, wherein the clamping circuit comprises a first resistance coupled to the first terminal of the second FET, and wherein a voltage of the gate terminal of the first FET is a difference between a threshold voltage of the first FET and a product of a resistance value of the first resistance and a current through the first FET.

4. The LDO regulator according to claim 2, wherein the clamping circuit comprises a current mirror and a third FET, a first terminal of the third FET is coupled to a first terminal of an input FET of the current mirror, and the first terminal of the first FET is coupled to a first terminal of an output FET of the current mirror.

5. The LDO regulator according to claim 4, wherein the third FET comprises a plurality of transistors that are connected in parallel and are configured to adjust a current through the input FET of the current mirror.

6. The LDO regulator according to claim 4, wherein a ratio between a current through the first FET and a current through the input FET of the current mirror is fixed when the clamping circuit is operating.

7. The LDO regulator according to claim 6, wherein the clamping circuit comprises a fourth FET, a first terminal of the fourth FET is coupled to a second terminal of the output FET of the current mirror, and a second terminal of the fourth FET is coupled to a second terminal of the second FET.

8. The LDO regulator according to claim 2, wherein the transistor and the first FET are transistors of the same type.

9. The LDO regulator according to claim 1, wherein the LDO regulator is coupled to a second LDO regulator, and the first terminal of the transistor in the LDO regulator is coupled to a first terminal of a transistor in the second LDO regulator.

10. The LDO regulator according to claim 9, wherein an output of a second clamping circuit is coupled to a gate terminal of the transistor in the second LDO regulator.

11. The LDO regulator according to claim 1, wherein the transistor is an n-channel metal-oxide-semiconductor (NMOS) transistor.

12. A memory device, comprising:
a memory cell array; and
a peripheral circuit coupled to the memory cell array and comprising an LDO regulator, and the LDO regulator comprises:
a transistor;
an amplifier; and
a clamping circuit, wherein:
an output of the LDO regulator is coupled to a first terminal of the transistor;
an output of the clamping circuit is coupled to a gate terminal of the transistor; and
an output of the amplifier is coupled to the gate terminal of the transistor.

13. The memory device according to claim 12, wherein the clamping circuit comprises a first field-effect transistor (FET) and a second FET, a gate terminal of the first FET is coupled to the gate terminal of the transistor, the gate terminal of the first FET is coupled to a first terminal of the second FET, and a first terminal of the first FET is coupled to a gate terminal of the second FET.

14. The memory device according to claim 13, wherein the clamping circuit comprises a first resistance coupled to the first terminal of the second FET, and wherein a voltage of the gate terminal of the first FET is a difference between a threshold voltage of the first FET and a product of a resistance value of the first resistance and a current through the first FET.

15. The memory device according to claim 13, wherein the clamping circuit comprises a current mirror and a third FET, a first terminal of the third FET is coupled to a first terminal of an input FET of the current mirror, and the first terminal of the first FET is coupled to a first terminal of an output FET of the current mirror.

16. The memory device according to claim 15, wherein the third FET comprises a plurality of transistors that are connected in parallel and are configured to adjust a current through the input FET of the current mirror.

17. The memory device according to claim 15, wherein a ratio between a current through the first FET and a current through the input FET of the current mirror is fixed when the clamping circuit is operating.

18. The memory device according to claim 17, wherein the clamping circuit comprises a fourth FET, a first terminal of the fourth FET is coupled to a second terminal of the output FET of the current mirror, and a second terminal of the fourth FET is coupled to a second terminal of the second FET.

19. The memory device according to claim 13, wherein the transistor and the first FET are transistors of the same type.

20. A memory system, comprising:
a memory device, comprising:
a memory cell array; and
a peripheral circuit coupled to the memory cell array and comprising an LDO regulator, and the LDO regulator comprises:
a transistor;
an amplifier; and
a clamping circuit, wherein:
an output of the LDO regulator is coupled to a first terminal of the transistor;
an output of the clamping circuit is coupled to a gate terminal of the transistor; and
an output of the amplifier is coupled to the gate terminal of the transistor; and
a controller coupled to the memory device and configured to send one or more signals to the memory device to initiate operations.
